(19) United States
(12) Patent Application Publication
(10) Pub. No.: US 2026/0123558 A1
(43) Pub. Date: Apr. 30, 2026

(54) SEMICONDUCTOR DEVICES WITH BONDING STRUCTURES AND METHODS FOR FORMING THE SAME

(71) Applicant: Yangtze Memory Technologies Co., Ltd., Wuhan (CN)

(72) Inventors: Lin LIN, Wuhan (CN); Chao WANG, Wuhan (CN); Feng TIAN, Wuhan (CN)

(21) Appl. No.: 18/952,595

(22) Filed: Nov. 19, 2024

(30) Foreign Application Priority Data
Oct. 31, 2024 (CN) 202411541375.9

(51) Int. Cl. H01L 23/00; H01L 25/065; H10B 80/00

(52) U.S. Cl. CPC H10W 99/00; H10W 72/90; H10B 80/00; H10W 72/019; H10W 72/01938; H10W 72/926; H10W 72/936; H10W 72/952; H10W 72/957; H10W 80/312; H10W 80/327; H10W 80/331; H10W 90/00; H10W 90/792

(57) ABSTRACT

The present disclosure relates to methods, devices, systems, and techniques for managing bonding structures in semiconductor devices. An example semiconductor device includes a first semiconductor structure, a bonding structure, and a second semiconductor structure stacked along a first direction. The first semiconductor structure is bonded to the second semiconductor structure through the bonding structure. The bonding structure includes a first group of contact structures, a second group of contact structures, and a dielectric material surrounding the first group of contact structures and the second group of contact structures. A first contact structure of the first group of contact structures is adjacent to a second contact structure of the second group of contact structures along a second direction perpendicular to the first direction. The first contact structure includes a first conductive material. The second contact structure includes the first conductive material and an oxide.

### CROSS-REFERENCE TO RELATED APPLICATIONS

This application claims priority to Chinese Patent Application No. 202411541375.9, filed on Oct. 31, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing bonding structures in semiconductor devices.

One aspect of the present disclosure features a semiconductor device. The semiconductor device includes a first semiconductor structure, a bonding structure, and a second semiconductor structure stacked along a first direction. The first semiconductor structure is bonded to the second semiconductor structure through the bonding structure. The bonding structure includes a first group of contact structures, a second group of contact structures, and a dielectric material surrounding the first group of contact structures and the second group of contact structures. A first contact structure of the first group of contact structures is adjacent to a second contact structure of the second group of contact structures along a second direction perpendicular to the first direction. The first contact structure includes a first conductive material. The second contact structure includes the first conductive material and an oxide.

In some implementations, the first conductive material is a first metal, the oxide is a metal oxide, the metal oxide is a chemical compound of oxygen and elements from a second conductive material, and the second conductive material is a second metal.

In some implementations, the first contact structure includes a first portion including the first conductive material, a second portion including the first conductive material, and a third portion including the first conductive material. The third portion is between the first portion and the second portion along the first direction. The first conductive material in the third portion is re-solidified.

In some implementations, the bonding structure includes a first dielectric layer in contact with the first semiconductor structure and a second dielectric layer in contact with the second semiconductor structure. The first group of contact structures and the second group of contact structures extend into the first dielectric layer and the second dielectric layer along the first direction. A first dielectric material of the first dielectric layer is bonded to a second dielectric material of the second dielectric layer.

In some implementations, the first semiconductor structure includes a first interconnect layer, the second semiconductor structure includes a second interconnect layer, the first interconnect layer is coupled to the second interconnect layer through the first group of contact structures.

In some implementations, the first semiconductor structure includes an array of memory cells, the second semiconductor structure includes peripheral circuits configured to control the array of memory cells. The array of memory cells are coupled to the peripheral circuits through the first group of contact structures.

In some implementations, the first semiconductor structure includes a first array of dynamic random access memory (DRAM) cells, the second semiconductor structure includes a second array of DRAM cells, and at least one of the first array or the second array is coupled to the first group of contact structures.

Another aspect of the present disclosure features a semiconductor device. The semiconductor device includes a first semiconductor structure, a bonding structure, and a second semiconductor structure stacked along a first direction. The first semiconductor structure is bonded to the second semiconductor structure through the bonding structure. The bonding structure includes contact structures and a dielectric material isolating the contact structures from one another. A first contact structure of the contact structures is conductive and includes a first portion including a conductive material, a second portion including the conductive material, and a third portion being between the first portion and the second portion along the first direction and including the conductive material and an oxide.

In some implementations, the conductive material is a first metal, the oxide is a metal oxide, and the metal oxide is a chemical compound of oxygen and elements from a second metal.

In some implementations, the bonding structure includes a first dielectric layer in contact with the first semiconductor structure and a second dielectric layer in contact with the second semiconductor structure. The contact structures extend into the first dielectric layer and the second dielectric layer along the first direction. A first dielectric material of the first dielectric layer is bonded to a second dielectric material of the second dielectric layer.

In some implementations, the first semiconductor structure includes a first interconnect layer, the second semiconductor structure includes a second interconnect layer, and the first interconnect layer is coupled to the second interconnect layer through the contact structures.

In some implementations, the first semiconductor structure includes an array of memory cells, the second semiconductor structure includes peripheral circuits configured to control the array of memory cells, and the array of memory cells are coupled to the peripheral circuits through the contact structures.

In some implementations, the first semiconductor structure includes a first array of DRAM cells, the second semiconductor structure includes a second array of DRAM cells, and at least one of the first array or the second array is coupled to the contact structures.

In some implementations, the semiconductor device includes two side regions and a center region between the two side regions along a second direction perpendicular to the first direction, and the contact structures are within the center region.

A further aspect of the present disclosure features a method of forming a semiconductor device. The method includes forming a first semiconductor structure and forming a second semiconductor structure. The method further includes forming a bonding structure between the first semiconductor structure and the second semiconductor structure along a first direction to bond the first semiconductor structure to the second semiconductor structure. Forming the bonding structure includes forming a first group of contact structures and a second group of contact structures of the bonding structure. A dielectric material of the bonding structure surrounds the first group of contact structures and the second group of contact structures. A first contact structure of the first group of contact structures is adjacent to a second contact structure of the second group of contact structures along a second direction perpendicular to the first direction. The first contact structure includes a first conductive material. The second contact structure includes the first conductive material and a first oxide.

In some implementations, forming the first group of contact structures and the second group of contact structures of the bonding structure includes forming a first bonding layer on a side of the first semiconductor structure. The first bonding layer includes the dielectric material, a first group of conductive pads, and a first group of thermite structures. The first group of conductive pads are coupled to a first interconnect layer of the first semiconductor structure. Forming the first group of contact structures and the second group of contact structures of the bonding structure can further include forming a second bonding layer on a side of the second semiconductor structure. The second bonding layer includes the dielectric material, a second group of conductive pads, and a second group of thermite structures. The second group of conductive pads are coupled to a second interconnect layer of the second semiconductor structure. The first group of conductive pads are associated with the second group of conductive pads along the first direction. The first group of thermite structures are associated with the second group of thermite structures along the first direction.

In some implementations, a first conductive pad of the first group of conductive pads is adjacent to a first thermite structure of the first group of thermite structures. The first conductive pad includes the first conductive material. The first conductive pad and the first thermite structure are isolated by the dielectric material. A second conductive pad of the second group of conductive pads is adjacent to a second thermite structure of the second group of thermite structures. The second conductive pad includes the first conductive material. The second conductive pad and the second thermite structure are isolated by the dielectric material.

In some implementations, the first thermite structure includes a second conductive material. The second thermite structure includes a second oxide. The first conductive material includes a first metal. The second conducive material includes a second metal. The second oxide includes a chemical compound of oxygen and elements from the first metal.

In some implementations, the first thermite structure and the second thermite structure both include multiple layers of the second metal and the second oxide alternating with each other along the first direction.

In some implementations, the method further includes aligning the first semiconductor structure with the second semiconductor structure. The first conductive pad is aligned with the second conductive pad along the first direction, and the first thermite structure is aligned with the second thermite structure along the first direction. The method can further include stacking the first semiconductor structure on the second semiconductor structure to make the first group of conductive pads in contact with the second group of conductive pads and make the first group of thermite structures in contact with the second group of thermite structures. The method can further include triggering a chemical reaction between the first group of thermite structures and the second group of thermite structures. Heat produced by the chemical reaction can melt a side of the first conductive pad and a side of the second conductive pad and bond the first conductive pad to the second conductive pad. The first contact structure is formed from the first conductive pad and the second conductive pad, and the second contact structure is formed by the chemical reaction between the first thermite structure and the second thermite structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates an example semiconductor device.

FIG. 2 illustrates another example semiconductor device.

FIG. 3 illustrates another example semiconductor device.

FIG. 4A(1)-4C illustrate an example process of fabricating a semiconductor device.

FIGS. 5A-5D illustrate another example process of fabricating a semiconductor device.

FIG. 6 illustrates a flow chart of an example process of manufacturing a semiconductor device.

FIG. 7 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers and a high aspect ratio. For example, the memory device can have multiple decks, and each deck can have multiple layers. Bonding (e.g., metal-metal bonding) of multiple semiconductor structures is an important step in the manufacturing process of memory devices. In one or more implementations of the present disclosure, an example semiconductor device is provided. The semiconductor device includes a first semiconductor structure bonded to a second semiconductor structure through a bonding structure. The bonding structure includes a first group of contact structures, a second group of contact structures, and a dielectric material surrounding the first group of contact structures and the second group of contact structures. A first contact structure of the first group of contact structures is adjacent to a second contact structure of the second group of contact structures. The first contact structure includes a first conductive material. The second contact structure includes the first conductive material and an oxide. In some implementations, the bonding structure can be formed by the following process. For example, thermite structures can be formed near a bonding interface of the semiconductor device by depositing (e.g., using physical vapor deposition (PVD)) Al and a metal oxide (e.g., CuO or MgO) into thermite holes. A thermite reaction can be triggered between Al and the metal oxide. The heat released during the thermite reaction can be used to melt metal conductive pads near the bonding interface, thereby achieving metal-metal bonding.

Implementations of the present disclosure can provide one or more of the following technical advantages and/or benefits. First, the thermite holes can be formed at the same location as current dummy structures. For example, some of the dummy structures that are originally designed to be used as bonding pads can now be used to form the thermite structures. Thus, there is no need for additional structural design. Second, techniques to reduce a trigger temperature for the chemical reaction between the thermite structures can be applied, thereby imposing less restrictions on the fabrication process. Therefore, the described techniques can improve the product yield and reduce the fabrication costs.

The techniques can be applied to any semiconductor structures or devices that are configured to avoid electric leakage or breakdown, e.g., between conductive layers or components. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

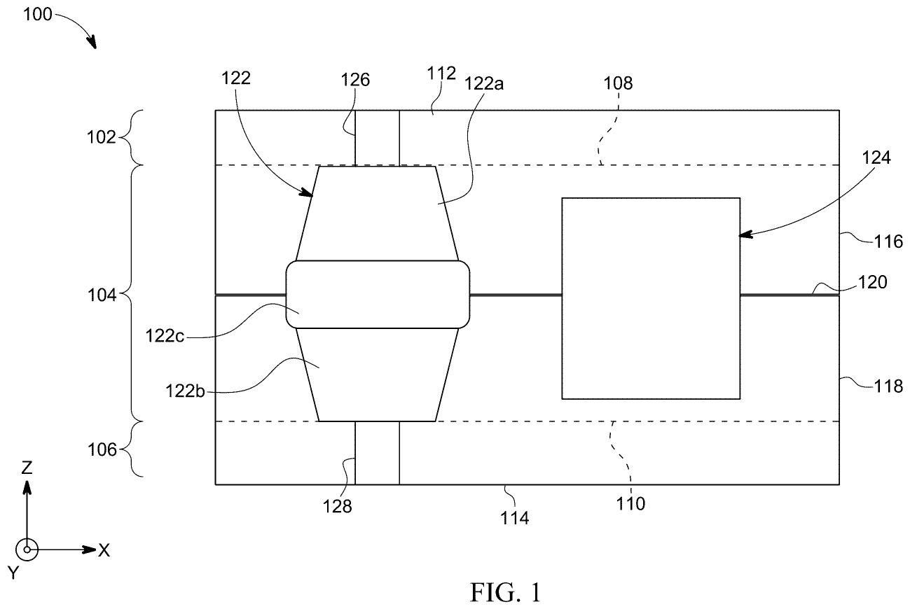

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates an example semiconductor device 100. In some implementations, the semiconductor device 100 can be a memory device, such as a three-dimensional (3D) NAND memory device or a 3D dynamic random access memory (DRAM) device. As shown in FIG. 1, the semiconductor device 100 can include a semiconductor structure 102, a bonding structure 104, and a semiconductor structure 106 stacked along a vertical direction (e.g., the Z direction). The semiconductor structure 102 is bonded to the semiconductor structure 106 through the bonding structure 104. For example, as shown in FIG. 1, the semiconductor structure 102 can have a side 108 in contact with a first side of the bonding structure 104, and the semiconductor structure 106 can have a side 110 in contact with a second side the bonding structure 104 opposite to the first side along the Z direction. The bonding structure 104 can include a dielectric layer 116 at the first side and a dielectric layer 118 at the second side. The dielectric layer 116 and the dielectric layer 118 can be bonded at a bonding interface 120. In some examples, the bonding interface 120 can be a layer with a certain thickness that includes a surface of the dielectric layer 116 and a surface of the dielectric layer 118. The bonding structure 104 can further include a group of contact structures 122 and a group of contact structures 124. The group of contact structures 122 and the group of contact structures 124 can extend into the dielectric layer 116 and the dielectric layer 118 along the Z direction. Each of the dielectric layers 116 and 118 can include a dielectric material being in contact with and surrounding the group of contact structures 122 and the group of contact structures 124 along a direction perpendicular to the vertical direction (e.g., in the X-Y plane). In other words, the dielectric material of the dielectric layer 116 and the dielectric material of the dielectric layer 118 can isolate one contact structure of the group contact structures 122 from another contact structure of the group contact structures 122 (e.g., in the X-Y plane). Similarly, the dielectric material of the dielectric layer 116 and the dielectric material of the dielectric layer 118 can isolate one contact structure of the group contact structures 124 from another contact structure of the group contact structures 124 (e.g., in the X-Y plane). The dielectric material of the dielectric layer 116 is bonded to the dielectric material of the dielectric layer 118 at the bonding interface 120 along the Z direction. In some implementations, the dielectric material of the dielectric layer 116 and the dielectric material of the dielectric layer 118 are of the same type (e.g., silicon oxide, silicon nitride, silicon oxynitride, low K dielectrics, or any combination thereof). Alternatively, the dielectric material of the dielectric layer 116 and the dielectric material of the dielectric layer 118 can be different types of dielectric materials. A contact structure 122 of the group of contact structures 122 can be adjacent to at least one contact structure 124 of the group of contact structures 124 (e.g., in the X-Y plane).

As shown in FIG. 1, the semiconductor structure 102 includes an interconnect layer 112 at the side 108, and the semiconductor structure 106 includes an interconnect layer 114 at the side 110. An interconnect layer (e.g., the interconnect layer 112 or 114) can include interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “intermetal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include dielectric materials including, but not limited to, silicon oxide, silicon nitride, silicon oxynitride, low dielectric constant (low K) dielectrics, or any combination thereof. For example, the interconnect layer 112 can include interconnects 126, and the interconnect layer 114 can include interconnects 128. The group of contact structures 122 can be coupled to the interconnects 126 and 128. In other words, the interconnect layer 112 can be coupled to the interconnect layer 114 through the group of contact structures 122.

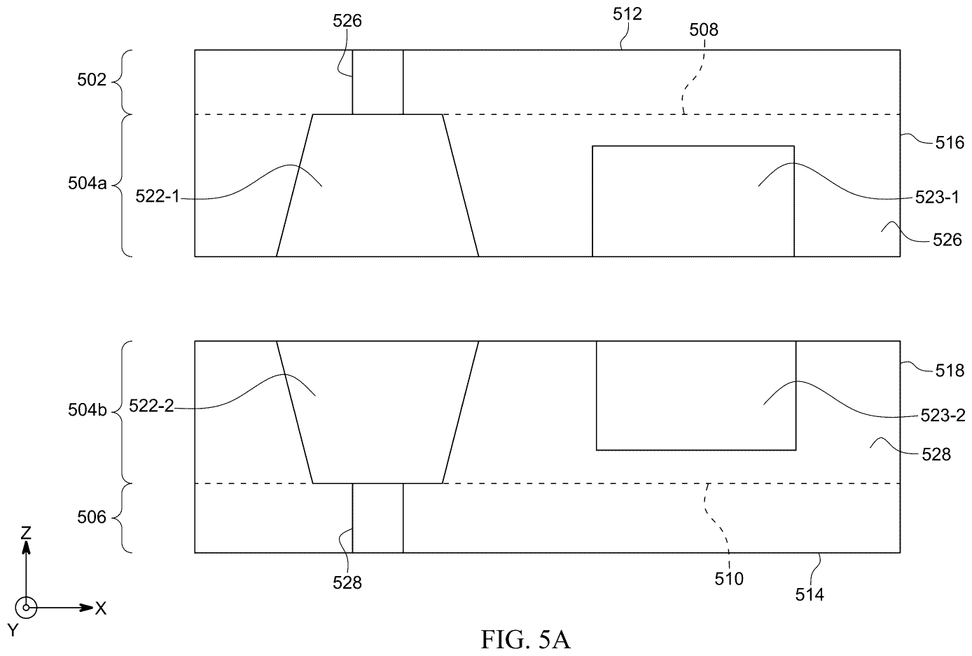

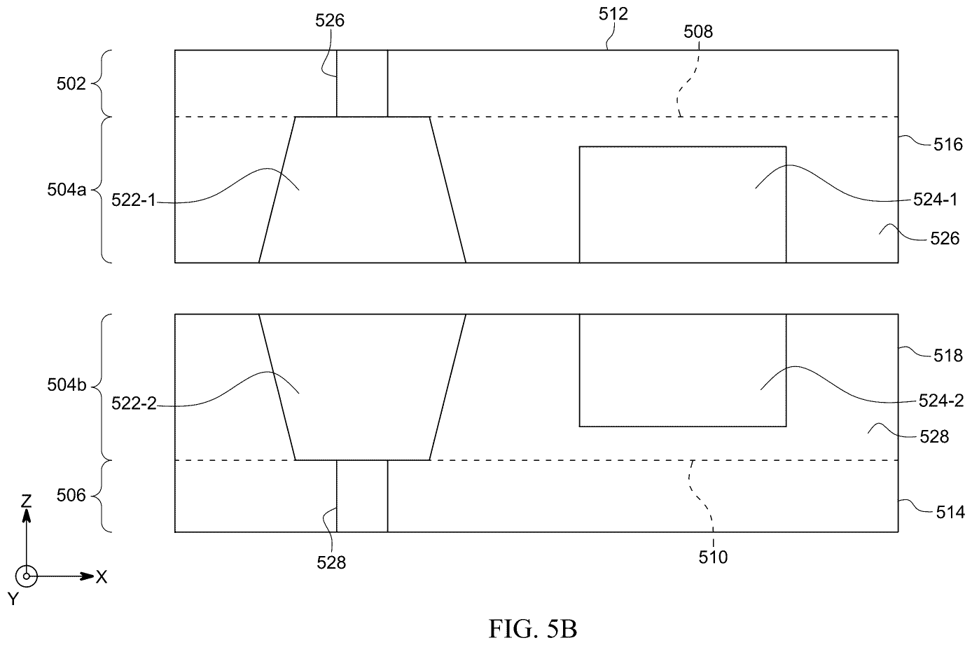

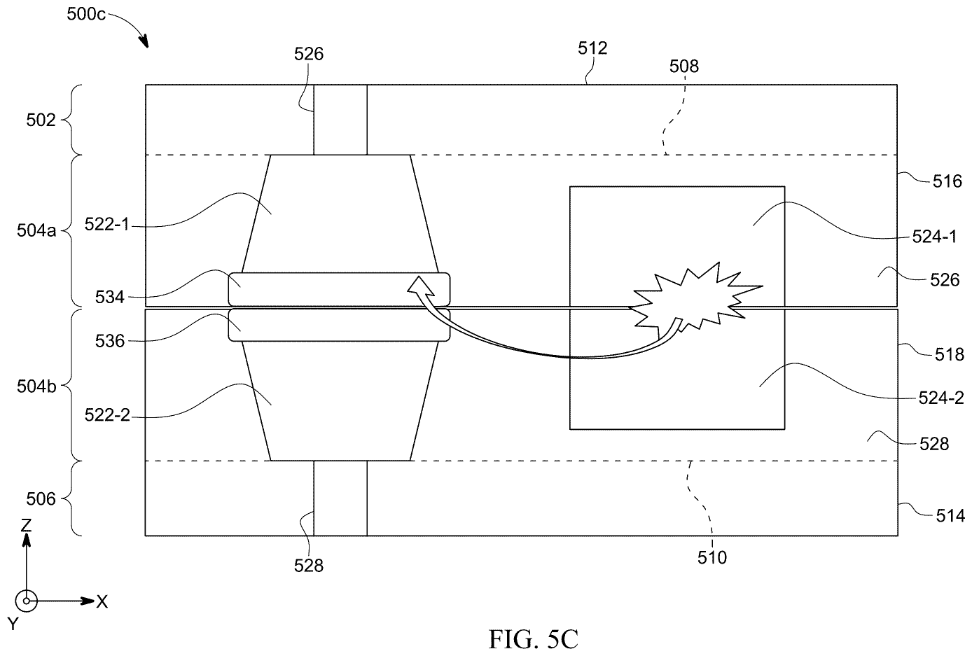

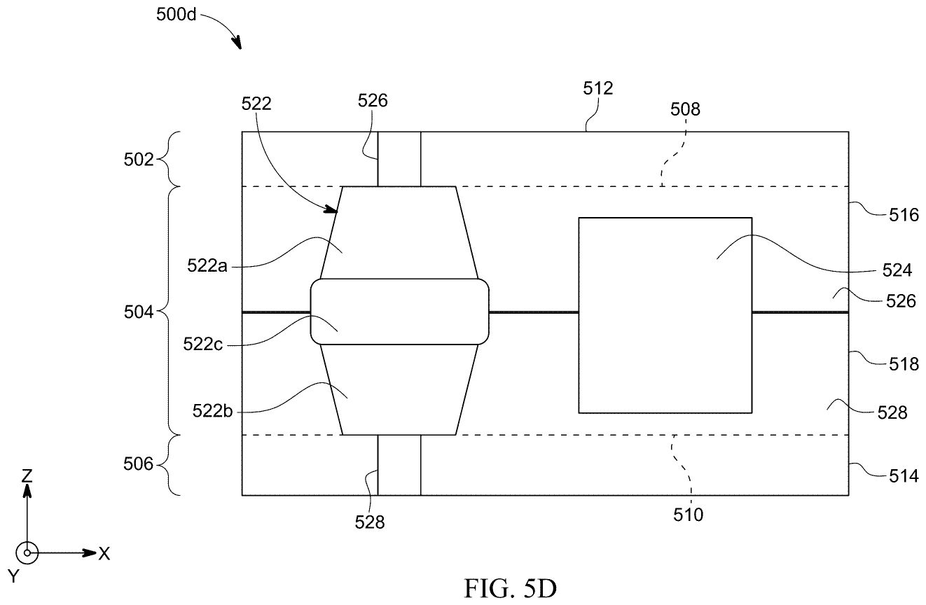

In some implementations, the bonding structure 104 is formed by hybrid bonding (also known as “metal/dielectric hybrid bonding”). Hybrid bonding is a direct bonding technology that forms bonding between surfaces without using intermediate layers, such as solder or adhesives. Hybrid bonding techniques can obtain metal-metal bonding and dielectric-dielectric bonding simultaneously. For example, the dielectric layer 116 is bonded to the dielectric layer 118 by dielectric-dielectric bonding. The contact structure 122 can be formed by metal-metal bonding. Example fabrication processes of the bonding structure 104 are described below in further detail in reference to FIGS. 5A-5D.

The contact structure 122 can include a first conductive material. The contact structure 124 can include the first conductive material and an oxide. The first conductive material can be a first metal (e.g., Cu). The oxide can be a metal oxide. In some implementations, the metal oxide is a chemical compound of oxygen and elements from a second conductive material. In some implementations, the second conductive material is a second metal. For example, the metal oxide can be Aluminium oxide (e.g., Al₂O₃), and the second metal can be Al. As shown in FIG. 1, the contact structure 122 can include a first portion 122a, a second portion 122b, and a third portion 122c. The portion 122c is between the portion 122a and the portion 122b along the Z direction. Each of the portions 122a, 122b, and 122c can include the first conductive material (e.g., Cu). The first conductive material in the portion 122c can be re-solidified.

In some implementations, the semiconductor structures 102 and 106 can be semiconductor wafers. In some other implementations, the semiconductor structures 102 and 106 can be semiconductor dies. For example, the semiconductor device 100 can be diced from wafers that are bonded together.

In some implementations, the semiconductor structure 102 can include an array of memory cells and thus can be referred to as an array wafer or an array die. The semiconductor structure 106 can include peripheral circuits configured to control the array of memory cells in the semiconductor structure 102. In some examples, the peripheral circuits in the semiconductor structure 106 are formed using complementary metal-oxide-semiconductor (CMOS) technology, and the semiconductor structure 106 can be referred to as a CMOS wafer or a CMOS die. The array of memory cells in the semiconductor structure 102 can be coupled to the peripheral circuits in the semiconductor structure 106 through the group of contact structures 122.

In some implementations, the semiconductor structure 102 includes a first array of DRAM cells. The semiconductor structure 106 can include a second array of DRAM cells. At least one of the first array or the second array is coupled to the group of contact structures 122.

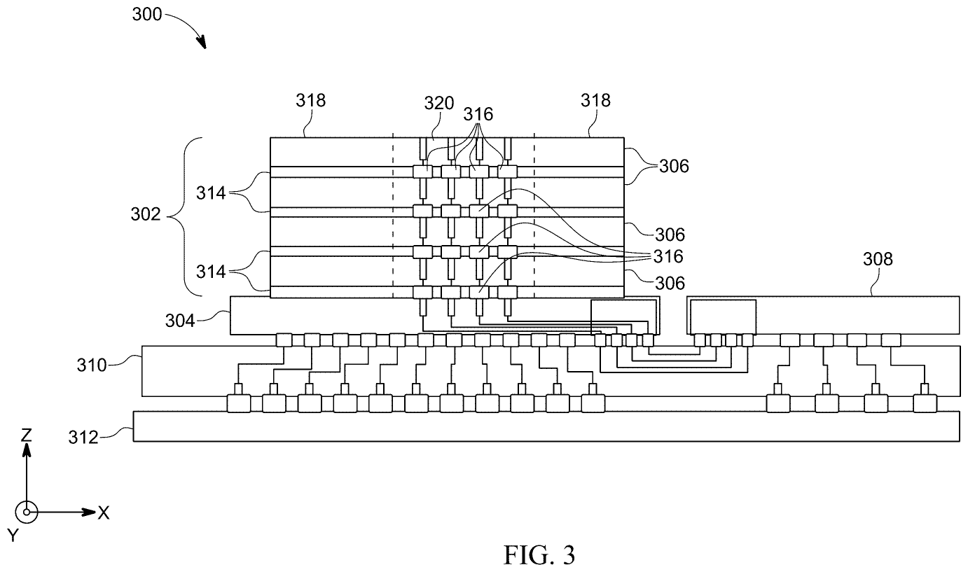

While FIG. 1 shows that the semiconductor device 100 includes two semiconductor structures bonded through one bonding structure, it is understood that this example is not intended to be construed in a limiting sense. In some implementations (e.g., as shown in FIG. 3), the semiconductor device 100 can include any suitable number (e.g., more than two) of semiconductor structures bonded through any suitable number (e.g., more than one) of bonding structures.

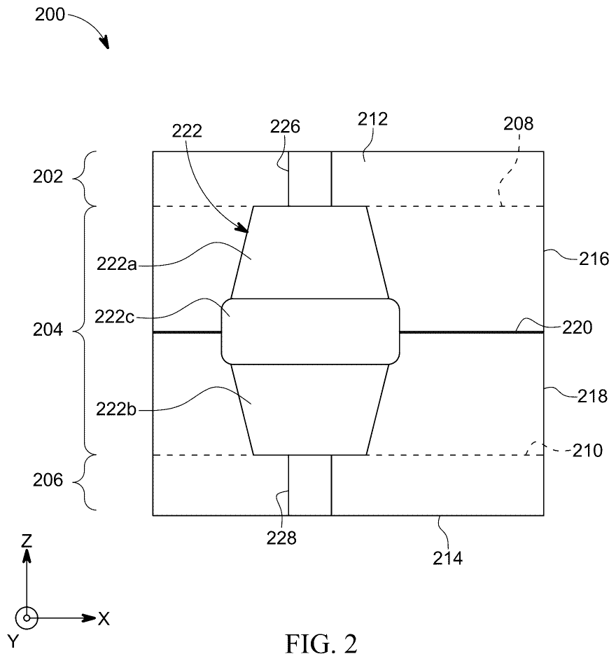

FIG. 2 illustrates an example semiconductor device 200. In some implementations, the semiconductor device 200 can be a memory device, such as a 3D NAND memory device or a 3D DRAM device. As shown in FIG. 2, the semiconductor device 200 can include a semiconductor structure 202, a bonding structure 204, and a semiconductor structure 206 stacked along the Z direction. The semiconductor structure 202 is bonded to the semiconductor structure 206 through the bonding structure 204. For example, as shown in FIG. 2, the semiconductor structure 202 can have a side 208 in contact with a first side of the bonding structure 204, and the semiconductor structure 206 can have a side 210 in contact with a second side the bonding structure 204 opposite to the first side along the Z direction. The bonding structure 204 can include a dielectric layer 216 at the first side and a dielectric layer 218 at the second side. The dielectric layer 216 and the dielectric layer 218 can be bonded at a bonding interface 220. In some examples, the bonding interface 220 can be a layer with a certain thickness that includes a surface of the dielectric layer 216 and a surface of the dielectric layer 218. The bonding structure 204 can further include contact structures 222. The contact structures 222 can extend into the dielectric layer 216 and the dielectric layer 218 along the Z direction. Each of the dielectric layers 216 and 218 can include a dielectric material being in contact with and surrounding the contact structures 222 along a direction perpendicular to the vertical direction (e.g., in the X-Y plane). In other words, the dielectric material of the dielectric layer 216 and the dielectric material of the dielectric layer 218 can isolate the contact structures 222 from one another (e.g., in the X-Y plane). The dielectric material of the dielectric layer 216 is bonded to the dielectric material of the dielectric layer 218 at the bonding interface 220 along the Z direction. In some implementations, the dielectric material of the dielectric layer 216 and the dielectric material of the dielectric layer 218 are of the same type (e.g., silicon oxide, silicon nitride, silicon oxynitride, low K dielectrics, or any combination thereof). Alternatively, the dielectric material of the dielectric layer 216 and the dielectric material of the dielectric layer 218 can be different types of dielectric materials.

As shown in FIG. 2, the semiconductor structure 202 includes an interconnect layer 212 at the side 208, and the semiconductor structure 206 includes an interconnect layer 214 at the side 210. The interconnect layer 212 can include interconnects 226, and the interconnect layer 214 can include interconnects 228. The contact structures 222 can be coupled to the interconnects 226 and 228. In other words, the interconnect layer 212 can be coupled to the interconnect layer 214 through the contact structures 222.

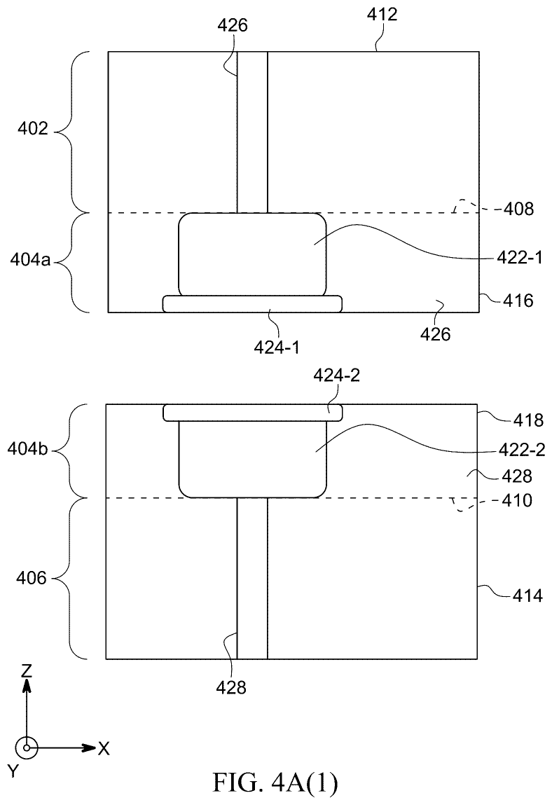

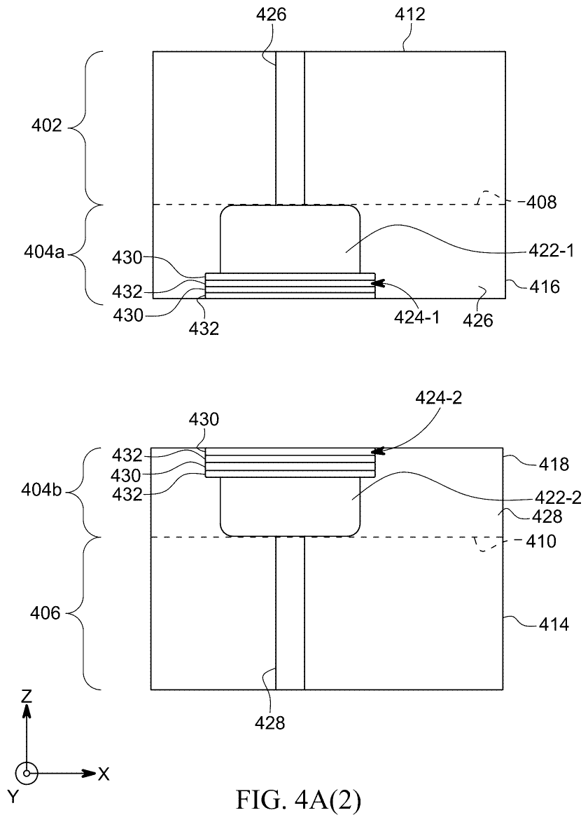

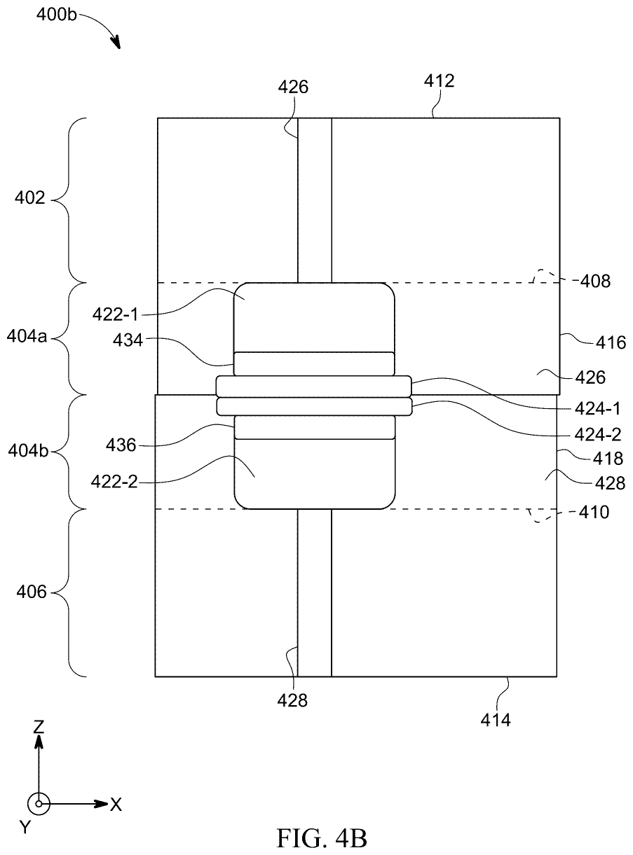

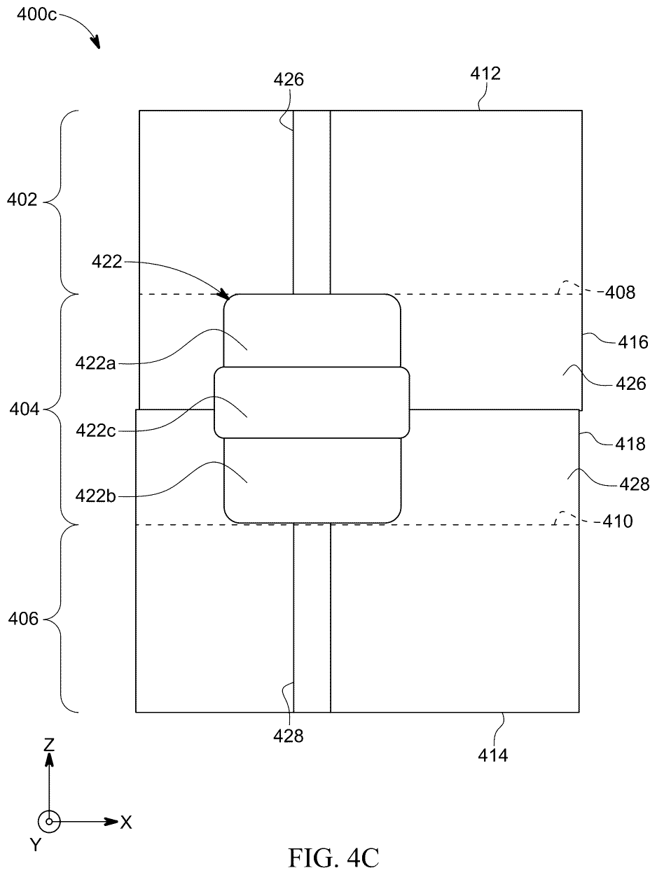

In some implementations, the bonding structure 204 is formed by hybrid bonding. For example, the dielectric layer 216 is bonded to the dielectric layer 218 by dielectric-dielectric bonding. The contact structure 222 can be formed by metal-metal bonding. Example fabrication processes of the bonding structure 204 are described below in further detail in reference to FIG. 4A(1)-4C.

As shown in FIG. 2, the contact structure 222 can include a first portion 222a, a second portion 222b, and a third portion 222c. The portion 222c is between the portion 222a and the portion 222b along the Z direction. Each of the portions 222a and 222b can include a same conductive material. The conductive material can be a first metal (e.g., Cu). The portion 222c can include the conductive material and an oxide. The oxide of the portion 222c can be a metal oxide. In some implementations, the metal oxide is a chemical compound of oxygen and elements from a second metal material. For example, the metal oxide can be Aluminium oxide (e.g., Al₂O₃), and the second metal can be Al. The conductive material in the portion 222c can be re-solidified.

The portion 222c can be conductive. In some implementations, the portion 222c can include any suitable amount of the conductive material and any suitable amount of the oxide to have a good electrical conductivity. For example, when the conductive material is Cu and the oxide is Al₂O₃, the portion 222c can have a high electrical conductivity (e.g., 90% International Annealed Copper Standard (IACS)) if a percentage (e.g., by volume) of the Al₂O₃ in the portion 222c is approximately 4.5 vol %. In this example, a percentage (e.g., by weight) of the Al can be approximately 0.8 wt %, and a percentage (e.g., by weight) of the O can be approximately 1.5 wt %.

In some implementations, the semiconductor structures 202 and 206 can be semiconductor wafers. In some other implementations, the semiconductor structures 202 and 206 can be semiconductor dies. For example, the semiconductor device 200 can be diced from wafers that are bonded together.

In some implementations, the semiconductor structure 202 can include an array of memory cells and thus can be referred to as an array wafer or an array die. The semiconductor structure 206 can include peripheral circuits configured to control the array of memory cells in the semiconductor structure 202. In some examples, the peripheral circuits in the semiconductor structure 206 are formed using CMOS technology, and the semiconductor structure 206 can be referred to as a CMOS wafer or a CMOS die. The array of memory cells in the semiconductor structure 202 can be coupled to the peripheral circuits in the semiconductor structure 206 through the contact structures 222.

In some implementations, the semiconductor structure 202 includes a first array of DRAM cells. The semiconductor structure 206 can include a second array of DRAM cells. At least one of the first array or the second array is coupled to the contact structures 222.

While FIG. 2 shows that the semiconductor device 200 includes two semiconductor structures bonded through one bonding structure, it is understood that this example is not intended to be construed in a limiting sense. In some implementations (e.g., as shown in FIG. 3), the semiconductor device 200 can include any suitable number (e.g., more than two) of semiconductor structures bonded through any suitable number (e.g., more than one) of bonding structures.

FIG. 3 is a block diagram of an example high bandwidth memory (HBM) device 300. HBM devices can use stacked memory dies or memory devices to enable effective data movement and access. While using less power in a smaller form factor, HBM devices can achieve higher bandwidth. HBM devices have been applied to high-performance graphics accelerators, network devices, high-performance datacenter, artificial intelligence (AI) and machine learning (ML) training, and various supercomputers. As shown in FIG. 3, the HBM device 300 can include a memory device 302, a base device 304, a computing device 308, an interposer 310, and an interface 312. The memory device 302 and the base device 304 can be stacked (e.g., sequentially) along the Z direction. The base device 304 and the computing device 308 can be integrated on different positions of the interposer 310 along the X direction.

In some implementations, each of devices 302, 304, 308, 310, and 312 can be a die or multiple dies stacked together. Each of devices 302, 304, 308, 310, and 312 can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die can include a fully functional electronic circuit, which can be a microprocessor, memory, sensor, or any other suitable type of integrated circuit. In some embodiments, each die is encapsulated in a protective package, providing physical support, protection from environmental factor, and connections (e.g., through pins or solder balls) to external devices or system.

The memory device 302 can include any suitable memory device as described with respect to FIGS. 1-2. In some implementations, as shown in FIG. 3, the memory device 302 includes DRAM devices 306 stacked along the Z direction. The memory device 302 further includes bonding structures 314. Two adjacent DRAM devices 306 can be bonded together by one of the bonding structures 314 between the two adjacent DRAM devices 306 along the Z direction. The bonding structure 314 also can be used to bond the DRAM device 306 to the base device 304. In some implementations, a DRAM device 306 can be an implementation of the semiconductor structure 102 or the semiconductor structure 106 as described with reference to FIG. 1. In some implementations, a DRAM device 306 can be an implementation of the semiconductor structure 202 or the semiconductor structure 206 as described with reference to FIG. 2. The bonding structure 314 can be an implementation of the bonding structure 104 of FIG. 1 or the bonding structure 204 of FIG. 2.

As shown in FIG. 3, each bonding structure 314 can include contact structures 316 (e.g., the contact structures 122 of FIG. 1 or the contact structures 222 of FIG. 2) that are coupled to interconnects of adjacent DRAM devices 306. The contact structures 316 in different bonding structures 314 can be aligned along the Z direction. In some implementations, the memory device 302 can include two side regions 318 and one center region 320 arranged along the X direction. The center region 320 is between the side regions 318 along the X direction. The contact structures 316 can be located within the center region 320. The example of FIG. 3 is not intended to be construed in a limiting sense, and any suitable arrangement of the contact structures 316 can be applied. For example, the contact structures 316 can be located within one or both of the side regions 318 of FIG. 3. In another example, the memory device 302 can have one side region 318 adjacent to another side region 318 along the X direction, and the contact structures 316 can be located in one side (e.g., within one of the side regions 318).

The base device 304 (also referred to as a logic die or a buffer die) can include buffer circuitry and test logic for memory device 302. The base device 304 can be configured to provide physical layer communication protocols (e.g., IEEE-1500) between memory device 302 and computing device 308. Base device 304 can be configured to transmit data between memory device 302 and computing device 308 based on control commands and addresses from computing device 308.

The computing device 308 can be a logic device and can include at least one processor of an electronic device, such as a central processing unit (CPU), a graphics processing unit (GPU), an application-specific integrated circuit (ASIC), or a system-on-chip (SoC), such as an application processor (AP). Computing device 308 can be configured to send or receive data to or from memory device 302. Computing device 308 is coupled to base device 304 through the interposer 310. The interposer 310 can include interconnection lines that connect the computing device 308 to the base device 304.

The HBM device 300 can be coupled to an external host (not shown in FIG. 3) through an interface 312. For example, the external host can be a computer, and the computing device 308 can be a CPU of the computer. In this example, the interface 312 can include connections provided by a mainboard of the computer that are coupled to the CPU. As another example, the external host is a graphics card, the computing device 308 is a GPU of the graphics card, and interface 312 can include connections provided by a printed circuit board (PCB) of the graphics card that are coupled to the GPU. In some implementations, the interface 312 can be a package substrate that is configured to provide physical support for the HBM device 300 and/or connections (e.g., data signal or power supply) from an external device or system to the HBM device 300.

The HBM device 300 may further include a memory controller (a.k.a., a controller circuit, which is not shown in FIG. 3) coupled to memory device 302. In some implementations, the memory controller is located in the computing device 308. Consistent with implementations of the present disclosure, the memory controller can include conductive interconnections through a cover layer that are in contact with conductive pads in a conductive pad layer, and the memory controller can be coupled to memory device 302 through at least one of the conductive interconnections. The memory controller is configured to control memory device 302. For example, the memory controller may be configured to operate channel structures via word lines. The memory controller can manage data stored in memory device 302 and communicate with computing device 308.

In some implementations, the memory controller is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller is designed/configured for operating in a high duty cycle environment SSDs or embedded multi-media-cards (eMMCs) used as data storage for mobile devices, such as smartphones, tablets, laptop computers, etc., and enterprise storage arrays. The memory controller can be configured to control operations of memory device 302, such as read, erase, and program (or write) operations. The memory controller can also be configured to manage various functions with respect to the data stored or to be stored in memory device 302 including, but not limited to bad-block management, garbage collection, logical-to-physical address conversion, wear leveling, etc. In some implementations, the memory controller is further configured to process error correction codes (ECCs) with respect to the data read from or written to memory device 302. In some other implementations, the base device 304 instead of the memory controller is configured to process ECCs. Any other suitable functions may be performed by the memory controller as well, for example, formatting memory device 302.

FIG. 4A(1)-4C illustrate an example process of fabricating a semiconductor device, such as the semiconductor device 200 as illustrated in FIG. 2. FIG. 4A(1)-4C show side views of example semiconductor structures at various stages of the fabrication process.

As shown in FIG. 4A(1), a semiconductor structure 402 is formed. A semiconductor structure 406 is also formed. The semiconductor structure 402 includes an interconnect layer 412 at a side 408, and the semiconductor structure 406 includes an interconnect layer 414 at a side 410. The interconnect layer 412 can include interconnects 426, and the interconnect layer 414 can include interconnects 428.

A bonding layer 404a can be formed on the side 408 of the semiconductor structure 402. The bonding layer 404a can include a dielectric layer 416, conductive pads 422-1, and thermite structures 424-1. The dielectric layer 416 can include a dielectric material 426. The conductive pads 422-1 can be coupled to the interconnect layer 412 of the semiconductor structure 402. Each of the thermite structures 424-1 can be in contact with a corresponding conductive pad 422-1 along the Z direction. The dielectric material 426 is in contact with and surrounding the contact pads 422-1 and the thermite structures 424-1 (e.g., in the X-Y plane). The dielectric material 426 can isolate the contact pads 422-1 from one another (e.g., in the X-Y plane) and isolate the thermite structures 424-1 from one another (e.g., in the X-Y plane).

A bonding layer 404b can be formed on the side 410 of the semiconductor structure 406. The bonding layer 404b can include a dielectric layer 418, conductive pads 422-2 and thermite structures 424-2. The dielectric layer 418 can include a dielectric material 428. The conductive pads 422-2 can be coupled to the interconnect layer 414 of the semiconductor structure 406. Each of the thermite structures 424-2 can be in contact with a corresponding conductive pad 422-2 along the Z direction. The dielectric material 428 is in contact with and surrounding the contact pads 422-2 and the thermite structures 424-2 (e.g., in the X-Y plane). The dielectric material 428 can isolate the contact pads 422-2 from one another (e.g., in the X-Y plane) and isolate the thermite structures 424-2 from one another (e.g., in the X-Y plane).

In some implementations, the conductive pads 422-1, the thermite structures 424-1, the conductive pads 422-2, and the thermite structures 424-2 are arranged in the bonding layers 404a and 404b so that each conductive pad 422-1 can be aligned with a corresponding thermite structure 424-1, a corresponding conductive pad 422-2, and a corresponding thermite structure 424-2 along the Z direction.

In some implementations, the conductive pad 422-1 can include a first conductive material. The first conductive material can be a first metal (e.g., Cu). The conductive pad 422-2 can also include the first conductive material. The thermite structure 424-1 and the termite structure 424-2 that are aligned along the Z direction can be referred to as a pair of thermite structures. In some implementations, one of the pair of thermite structures (e.g., thermite structure 424-1) can include a second conductive material. The second conductive material can be a second metal (e.g., Al). Another of the pair of thermite structures (e.g., thermite structure 424-2) can include an oxide. The oxide can be a metal oxide (e.g., CuO, MgO, MnO, Fe₃O₄) that can generate a thermite reaction with the second conductive material. For example, the metal oxide (e.g., CuO) is a chemical compound of oxygen and elements from the first conductive material (e.g., Cu). As described below in further detail, the thermite structures 424-1 and the thermite structures 424-2 can be configured to trigger a chemical reaction between them. The heat produced by the chemical reaction can melt a side of the conductive pads 422-1 and a side of the conductive pads 422-2 and bond the conductive pads 422-1 and 422-2 together.

In some implementations, each of the thermite structures 424-1 can have one single layer, and each of the thermite structures 424-2 can also have one single layer. The thermite structure 424-1 and the thermite structure 424-2 can have suitable thickness (e.g., a size along the Z direction) and suitable densities of the second metal (e.g., Al) and the metal oxide (e.g., CuO). In this way, sufficient heat can be generated in the chemical reaction to melt the conductive pads 422-1 and the conductive pads 422-2. In some implementations, a suitable arrangement of the thermite structure 424-1 and 424-2 can be determined based on factors including, but not limited to, a size of the conductive pads 422-1 and 422-2, the heat required to melt the conductive pads 422-1 and 422-2, and the heat released from the chemical reaction of the thermite structures 424-1 and 424-2. For example, assuming that an ambient temperature is 20° C., a specific heat capacity of Cu is 3.90E+02, a melting point of Cu is 1080° C., a density of solid Cu is 8.96 g/cm3, and a density of liquid Cu is 8.92 g/cm3, then the heat required for Cu to transition to a molten state is: 3900*(1080-20)=413400 (J/kg). Based on the reaction equation: 2Al+3CuO→Al2O3+3Cu2 and parameters such as density of Al₂O₃, Al, and CuO, the energy (e.g., per unit volume) required for Cu to melt is: 413400/(8.96*1000)≈46 (J/cm³), and the heat (e.g., per unit volume) released by the Al/CuO system is: 3900000/(6.26*1000)≈623 (J/cm³). In some implementations, the suitable arrangement of the thermite structure 424-1 and 424-2 can be selected to achieve uniform heat dissipation. In some implementations, the chemical reaction can be triggered in a temperature between 1000° C. and 1500° C. (e.g., 1250° C.) or even higher.

FIG. 4A(2) illustrates another implementation of the bonding layer 404a and the bonding layer 404b. The semiconductor structure 402 and the semiconductor structure 406 of FIG. 4A(2) can be the same as the semiconductor structure 402 and the semiconductor structure 406 of FIG. 4A(1). The bonding layers 404a and 404b of FIG. 4A(2) can be similar to the bonding layers 404a and 404b of FIG. 4A(1). One difference between FIG. 4A(2) and FIG. 4A(1) is that each of the thermite structures 424-1 of FIG. 4A(2) and each of the thermite structures 424-2 of FIG. 4A(2) can have multiple layers. As shown in FIG. 4A(2), the thermite structure 424-1 include multiple metal layers 430 and multiple metal oxide layers 432 stacked along the Z direction. The metal layers 430 and the metal oxide layers 432 alternating with each other along the Z direction. Similarly, the thermite structure 424-2 can also include multiple metal layers 430 and multiple metal oxide layers 432 being stacked along the Z direction and alternating with each other along the Z direction. The metal layers 430 can include the second metal (e.g., Al), and the metal oxide layers 432 can include the metal oxide (e.g., CuO). In some implementations, the structures of the thermite structures 424-1 and 424-2 as shown in FIG. 4A(2) can reduce the trigger temperature for the chemical reaction between the second metal and the metal oxide. In some implementations, a lower trigger temperature can impose less restrictions on the fabrication process. In some implementations, the trigger temperature can depend on a thickness (e.g., a size along the Z direction) of each metal layer 430 and a thickness (e.g., a size along the Z direction) of each metal oxide layer 432. For example, when a total thickness of the metal/metal oxide multilayer structure is kept constant at 1800 nm, the more layers there are and the thinner each individual layer is, the lower the reaction trigger temperature. When a total thickness of a metal/metal oxide bilayer (e.g., a metal layer 430 and an adjacent metal oxide layer 432) is less than 300 nm, the reaction trigger temperature is less than 680 Kelvin (K). In practice, suitable sizes can be selected for the metal layers 430 and the metal oxide layers 432 to achieve a target trigger temperature.

In practice, any suitable techniques configured to reduce the reaction trigger temperature can be applied to the fabrication process. In some implementations (not shown in FIG. 4A(2)), ultra-small chemically synthesized CuO nanoparticles coated with alkylamine ligands can be included in the thermite structures 424-1 or 424-2. These alkylamine ligands stabilize the CuO nanoparticles and enhance the interfacial contact between Al and CuO particles. The ligands can fragment into organic species accompanied with H₂O and CO² release, which promotes CuO reduction into Cu₂O and further Cu. In this way, the main decomposition processes can take place on the CuO surface at a lower temperature (e.g., <500° C.).

FIG. 4B illustrates a semiconductor structure 400b. The semiconductor structure 400b can be formed by aligning the semiconductor structure 402 (and the bonding layer 404a coupled to the semiconductor structure 402) with the semiconductor structure 406 (and the bonding layer 404b coupled to the semiconductor structure 406). Each of the conductive pads 422-1 can be aligned with a corresponding thermite structure 424-1, a corresponding thermite structure 424-2, and a corresponding conductive pad 422-2 (e.g., along the Z direction). The semiconductor structure 402 and the bonding layer 404a can be stacked on the semiconductor structure 406 and the bonding layer 404b to make each of the thermite structures 424-1 in contact with a corresponding thermite structure 424-2. In some implementations, the thermite structures 424-1 of FIG. 4B can be similar to, or same as, the thermite structures 424-1 of FIG. 4A(1), and the thermite structures 424-2 of FIG. 4B can be similar to, or same as, the thermite structures 424-2 of FIG. 4A(1). In some implementations, the thermite structures 424-1 of FIG. 4B can be similar to, or same as, the thermite structures 424-1 of FIG. 4A(2), and the thermite structures 424-2 of FIG. 4B can be similar to, or same as, the thermite structures 424-2 of FIG. 4A(2). Forming the semiconductor structure 400b further includes triggering a chemical reaction between the thermite structures 424-1 and the thermite structures 424-2. The heat produced by the chemical reaction can melt a side of the conductive pad 422-1 and a side of the conductive pad 422-2 aligned with the conductive pad 422-1 (e.g., along the Z direction). FIG. 4B illustrates a portion 434 of the conductive pad 422-1 that is melted and a portion 436 of the conductive pad 422-2 that is melted.

FIG. 4C illustrates a semiconductor structure 400c formed from the semiconductor structure 400b. The semiconductor structure 400c can be an implementation of the semiconductor device 200 of FIG. 2 or the semiconductor device 300 of FIG. 3. The semiconductor structure 400c includes a bonding structure 404. The bonding structure 404 includes the dielectric layer 416 and the dielectric layer 418 bonded together. The bonding structure 404 further includes contact structures 422. Each contact structure 422 can be formed by the conductive pad 422-1 and a corresponding conductive pad 422-2 bonded together. For example, the melted portion 434 and the melted portion 436 can re-solidify, and the re-solidified portion 434, the re-solidified portion 436, and the reaction result of the thermite structures 424-1 and 424-2 (as shown in FIG. 4B) can bond the conductive pad 422-1 and the corresponding conductive pad 422-2 together. As shown in FIG. 4C, the contact structure 422 can include a first portion 422a, a second portion 422b, and a third portion 422c. The portion 422c is between the portion 422a and the portion 422b along the Z direction. Each of the portions 422a and 422b can include a same conductive material (e.g., the first conductive material). The conductive material can be a metal (e.g., Cu). The portion 422c can include the conductive material and an oxide. The oxide of the portion 422c can be a metal oxide. In some implementations, the metal oxide (e.g., Al₂O₃) is a chemical compound of oxygen and elements from the second conductive material (e.g., Al). The conductive material in the portion 422c can be re-solidified.

FIGS. 5A-5D illustrate an example process of fabricating a semiconductor device, such as the semiconductor device 100 as illustrated in FIG. 1. FIGS. 5A-5D show side views of example semiconductor structures at various stages of the fabrication process.

As shown in FIG. 5A, a semiconductor structure 502 is formed. A semiconductor structure 506 is also formed. The semiconductor structure 502 includes an interconnect layer 512 at a side 508, and the semiconductor structure 506 includes an interconnect layer 514 at a side 510. The interconnect layer 512 can include interconnects 526, and the interconnect layer 514 can include interconnects 528.

A bonding layer 504a can be formed on the side 508 of the semiconductor structure 502. The bonding layer 504a can include a dielectric layer 516, conductive pads 522-1, and thermite holes 523-1. The dielectric layer 516 can include a dielectric material 526. The conductive pads 522-1 can be coupled to the interconnect layer 512 of the semiconductor structure 502. Each of the conductive pads 522-1 can be adjacent to at least one of the thermite holes 523-1 (e.g., in the X-Y plane). The dielectric material 526 is in contact with and surrounding the contact pads 522-1 and the thermite holes 523-1 (e.g., in the X-Y plane). The dielectric material 526 can isolate the contact pads 522-1 and the thermite holes 523-1 from one another (e.g., in the X-Y plane).

A bonding layer 504b can be formed on the side 510 of the semiconductor structure 506. The bonding layer 504b can include a dielectric layer 518, conductive pads 522-2 and thermite holes 523-2. The dielectric layer 518 can include a dielectric material 528. The conductive pads 522-2 can be coupled to the interconnect layer 514 of the semiconductor structure 506. Each of the conductive pads 522-2 can be adjacent to at least one of the thermite holes 523-2 (e.g., in the X-Y plane). The dielectric material 528 is in contact with and surrounding the contact pads 522-2 and the thermite holes 523-2 (e.g., in the X-Y plane). The dielectric material 528 can isolate the contact pads 522-2 and the thermite holes 523-2 from one another (e.g., in the X-Y plane).

In some implementations, the conductive pads 522-1, the thermite holes 523-1, the conductive pads 522-2, and the thermite holes 523-2 are arranged in the bonding layers 504a and 504b so that each conductive pad 522-1 can be aligned with a corresponding conductive pad 522-2 along the Z direction, and each thermite hole 523-1 can be aligned with a corresponding thermite hole 523-2 along the Z direction. In some implementations, the conductive pad 522-1 can include a first conductive material. The first conductive material can be a first metal (e.g., Cu). The conductive pad 522-2 can also include the first conductive material.

FIG. 5B illustrates the semiconductor structure 502, the semiconductor structure 506, the bonding layer 504a, and the bonding layer 504b, where the bonding layer 504a is formed from the bonding layer 504a of FIG. 5A, and the bonding layer 504b is formed form the bonding layer 504b of FIG. 5A. The bonding layer 504a includes thermite structures 524-1, which are formed by depositing (e.g., by using chemical vapor deposition (CVD) or physical vapor deposition (PVD)) one or more thermite materials into the thermite holes 523-1 of FIG. 5A. The bonding layer 504b includes thermite structures 524-2, which are formed by depositing one or more thermite materials into the thermite holes 523-2 of FIG. 5A. The thermite structure 524-1 and the termite structure 524-2 that are aligned along the Z direction can be referred to as a pair of thermite structures. In some implementations, one of the pair of thermite structures (e.g., thermite structure 524-1) can include a second conductive material. The second conductive material can be a second metal (e.g., Al). Another of the pair of thermite structures (e.g., thermite structure 524-2) can include an oxide. The oxide can be a metal oxide (e.g., CuO, MgO, MnO, Fe₃O₄) that can generate a thermite reaction with the second conductive material. For example, the metal oxide (e.g., CuO) is a chemical compound of oxygen and elements from the first conductive material (e.g., Cu). As described below in further detail, the thermite structures 524-1 and the thermite structures 524-2 can be configured to trigger a chemical reaction between them. The heat produced by the chemical reaction can melt a side of an adjacent conductive pads 522-1 and a side of an adjacent conductive pads 522-2 and bond the conductive pads 522-1 and 522-2 together.

Similar to the thermite structure 424-1 and the termite structure 424-2 described above in reference to FIG. 4A(1)-4A(2), the thermite structure 524-1 and the termite structure 524-2 can also have various structures. In some implementations, each of the thermite structures 524-1 can have one single layer, and each of the thermite structures 524-2 can also have one single layer. The thermite structure 524-1 and the thermite structure 524-2 can have suitable thickness (e.g., a size along the Z direction) and suitable densities of the second metal (e.g., Al) and the metal oxide (e.g., CuO). In this way, sufficient heat can be generated in the chemical reaction to melt the conductive pads 522-1 and the conductive pads 522-2. In some implementations, techniques for reducing a trigger temperature of the chemical reaction (e.g., thermite reaction) can be applied. For example, similar to the thermite structures 424-1 and 424-2 of FIG. 4A(2), each of the thermite structures 524-1 and 524-2 can have multiple layers. The thermite structure 524-1 can include multiple metal layers and multiple metal oxide layers being stacked along the Z direction and alternating with each other along the Z direction. Similarly, the thermite structure 524-2 can also include multiple metal layers and multiple metal oxide layers being stacked along the Z direction and alternating with each other along the Z direction. In practice, any suitable techniques configured to reduce the reaction trigger temperature can be applied to the fabrication process. In some implementations (not shown in FIG. 5B), ultra-small chemically synthesized CuO nanoparticles coated with alkylamine ligands can be included in the thermite structures 524-1 or 524-2. These alkylamine ligands stabilize the CuO nanoparticles and enhance the interfacial contact between Al and CuO particles. The ligands can fragment into organic species accompanied with H2O and CO2 release, which promotes CuO reduction into Cu2O and further Cu. In this way, the main decomposition processes can take place on the CuO surface at a lower temperature (e.g., <500° C.).

FIG. 5C illustrates a semiconductor structure 500c. The semiconductor structure 500c can be formed by aligning the semiconductor structure 502 (and the bonding layer 504a coupled to the semiconductor structure 502) with the semiconductor structure 506 (and the bonding layer 504b coupled to the semiconductor structure 506). Each of the conductive pads 522-1 can be aligned with a corresponding conductive pad 522-2 (e.g., along the Z direction). Each of the thermite structures 524-1 can be aligned with a corresponding thermite structure 424-2 (e.g., along the Z direction). The semiconductor structure 502 and the bonding layer 504a can be stacked on the semiconductor structure 506 and the bonding layer 504b to make each of the conductive pads 522-1 in contact with a corresponding conductive pad 522-2 and each of the thermite structures 524-1 in contact with a corresponding thermite structure 524-2. Forming the semiconductor structure 500c further includes triggering a chemical reaction between the thermite structures 524-1 and the thermite structures 524-2. The heat produced by the chemical reaction can melt a side of the conductive pad 522-1 and a side of the conductive pad 522-2 aligned with the conductive pad 522-1 (e.g., along the Z direction). FIG. 5C illustrates a portion 534 of the conductive pad 522-1 that is melted and a portion 536 of the conductive pad 522-2 that is melted.

FIG. 5D illustrates a semiconductor structure 500d formed from the semiconductor structure 500c. The semiconductor structure 500d can be an implementation of the semiconductor device 100 of FIG. 1 or the semiconductor device 300 of FIG. 3. The semiconductor structure 500d includes a bonding structure 504. The bonding structure 504 includes the dielectric layer 516 and the dielectric layer 518 bonded together. The bonding structure 504 further includes a group of contact structures 522 and a group of contact structures 524. Each contact structure of the group of contact structures 522 can be formed by the conductive pad 522-1 and a corresponding conductive pad 522-2 bonded together. For example, the melted portion 534 and the melted portion 536 can re-solidify to bond the conductive pad 522-1 and the corresponding conductive pad 522-2 together. Each contact structure 524 of the group of contact structures 524 can be formed by the reaction result of the thermite structures 524-1 and 524-2 (as shown in FIG. 5C).

As shown in FIG. 5D, the contact structure 522 can include a first portion 522a, a second portion 522b, and a third portion 522c. The portion 522c is between the portion 522a and the portion 522b along the Z direction. Each of the portions 522a, 522b, and 522c can include a same conductive material (e.g., the first conductive material). The conductive material can be a metal (e.g., Cu). The conductive material in the portion 522c can be re-solidified. The contact structure 524 can include the conductive material and an oxide. The oxide of the contact structure 524 can be a metal oxide. In some implementations, the metal oxide (e.g., Al₂O₃) is a chemical compound of oxygen and elements from the second conductive material (e.g., Al).

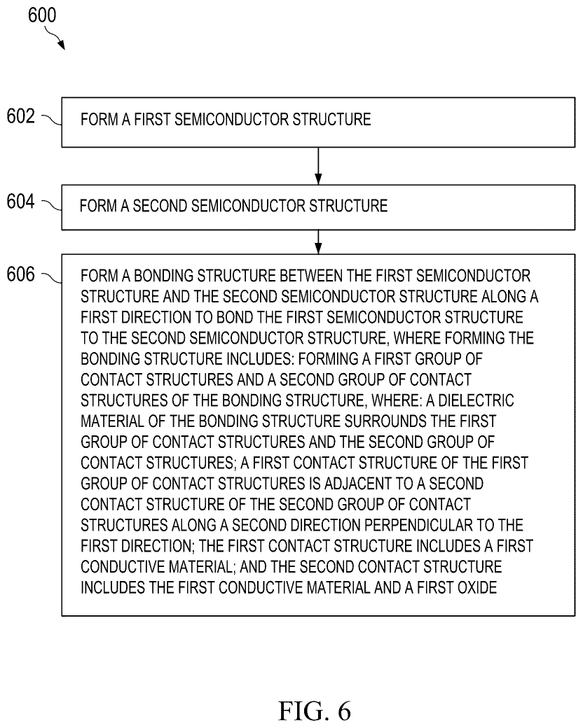

FIG. 6 illustrates a flow chart of an example process 600. The process 600 can be performed to form a semiconductor device (e.g., the semiconductor device 100 illustrated by FIG. 1, the semiconductor device 200 illustrated by FIG. 2, or the semiconductor device 300 illustrated by FIG. 3). The process 600 can be described in view of FIG. 5A-5D. The process 600 can include one or more steps of the fabrication process of forming the semiconductor structures in FIGS. 5A-5D. It is understood that the operations shown in process 600 are not exhaustive and that other operations can be performed as well before, after, or between any of the illustrated operations. Further, some of the operations may be performed simultaneously, or in a different order than shown in FIG. 6.

At operation 602, a first semiconductor structure (e.g., the semiconductor structure 502 of FIG. 5A) is formed.

At operation 604, a second semiconductor structure (e.g., the semiconductor structure 506 of FIG. 5A) is formed.

At operation 606, a bonding structure (e.g., the semiconductor structure 504 of FIG. 5D) is formed. The bonding structure is between the first semiconductor structure and the second semiconductor structure along a first direction (e.g., the Z direction) to bond the first semiconductor structure to the second semiconductor structure. Forming the bonding structure includes forming a first group of contact structures (e.g., the group of contact structures 522 of FIG. 5D) and a second group of contact structures (e.g., the group of contact structures 524 of FIG. 5D) of the bonding structure. A dielectric material (e.g., the dielectric material 526 or 528 of FIG. 5D) of the bonding structure surrounds the first group of contact structures and the second group of contact structures. A first contact structure (e.g., the contact structure 522 of FIG. 5D) of the first group of contact structures is adjacent to a second contact structure (e.g., the contact structure 524 of FIG. 5D) of the second group of contact structures along a second direction (e.g., the X direction) perpendicular to the first direction. The first contact structure includes a first conductive material (e.g., Cu). The second contact structure includes the first conductive material (e.g., Cu) and a first oxide (e.g., Al₂O₃).

In some implementations, the first conductive material includes a first metal (e.g., Cu). The first oxide includes a chemical compound of oxygen and elements from a second metal (e.g., Al).

In some implementations, forming the first group of contact structures and the second group of contact structures of the bonding structure includes forming a first bonding layer (e.g., the bonding layer 504a of FIG. 5B) on a side (e.g., the side 508) of the first semiconductor structure. The first bonding layer includes the dielectric material (e.g., the dielectric material 526), a first group of conductive pads (e.g., the conductive pads 522-1), and a first group of thermite structures (e.g., the thermite structures 524-1). The first group of conductive pads are coupled to a first interconnect layer (e.g., the interconnect layer 512) of the first semiconductor structure.

In some implementations, forming the first group of contact structures and the second group of contact structures of the bonding structure further includes forming a second bonding layer (e.g., the bonding layer 504b of FIG. 5B) on a side (e.g., the side 510) of the second semiconductor structure. The second bonding layer includes the dielectric material (e.g., the dielectric material 528), a second group of conductive pads (e.g., the conductive pads 522-2), and a second group of thermite structures (e.g., the thermite structures 524-2). The second group of conductive pads are coupled to a second interconnect layer (e.g., the interconnect layer 514) of the second semiconductor structure. The first group of conductive pads are associated with the second group of conductive pads along the first direction (e.g., the Z direction), and the first group of thermite structures are associated with the second group of thermite structures along the first direction (e.g., the Z direction).

In some implementations, a first conductive pad (e.g., the conductive pad 522-1) of the first group of conductive pads is adjacent to a first thermite structure (e.g., the thermite structure 524-1) of the first group of thermite structures. The first conductive pad includes the first conductive material (e.g., Cu). The first conductive pad and the first thermite structure are isolated by the dielectric material (e.g., the dielectric material 526). A second conductive pad (e.g., the conductive pad 522-2) of the second group of conductive pads is adjacent to a second thermite structure (e.g., the thermite structure 524-2) of the second group of thermite structures. The second conductive pad includes the first conductive material (e.g., Cu). The second conductive pad and the second thermite structure are isolated by the dielectric material (e.g., the dielectric material 528).

In some implementations, the first thermite structure (e.g., the thermite structure 524-1) includes a second conductive material (e.g., Al). The second thermite structure includes a second oxide (e.g., CuO). The first conductive material includes a first metal (e.g., Cu). The second conducive material includes a second metal (e.g., Al). The second oxide (e.g., CuO) includes a chemical compound of oxygen and elements from the first metal (e.g., Cu).

In some implementations, the first thermite structure (e.g., the thermite structure 424-1 of FIG. 4A(2)) and the second thermite structure (e.g., the thermite structure 424-2 of FIG. 4A(2)) both include multiple layers of the second metal (e.g., metal layers 430 of FIG. 4A(2)) and the second oxide (e.g., metal oxide layers 432 of FIG. 4A(2)) alternating with each other along the first direction (e.g., the Z direction).

In some implementations, the process 600 further includes aligning the first semiconductor structure with the second semiconductor structure (e.g., along the Z direction). The first conductive pad is aligned with the second conductive pad along the first direction (e.g., the Z direction), and the first thermite structure is aligned with the second thermite structure along the first direction (e.g., the Z direction).

In some implementations, the process 600 further includes stacking the first semiconductor structure on the second semiconductor structure to make the first group of conductive pads in contact with the second group of conductive pads and make the first group of thermite structures in contact with the second group of thermite structures.

In some implementations, the process 600 further includes triggering a chemical reaction between the first group of thermite structures and the second group of thermite structures. The heat produced by the chemical reaction can melt a side of the first conductive pad (e.g., the melted portion 534 of FIG. 5C) and a side of the second conductive pad (e.g., the melted portion 536 of FIG. 5C) and bonds the first conductive pad to the second conductive pad (e.g., as described in reference to FIG. 5D). The first contact structure (e.g., the contact structure 522 of FIG. 5D) is formed from the first conductive pad and the second conductive pad. The second contact structure (e.g., the contact structure 524 of FIG. 5D) is formed by the chemical reaction between the first thermite structure and the second thermite structure.

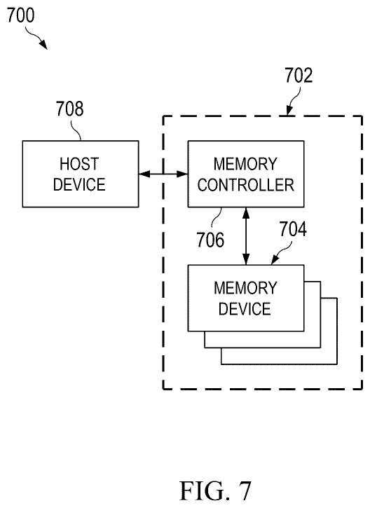

FIG. 7 illustrates a block diagram of an example system 700. The system 700 can have one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 7, the system 700 can include a host device 708 and a memory system 702 having one or more memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more memory devices 704.

A memory device 704 can be any memory device disclosed in the present disclosure, such as a memory device (e.g., a NAND Flash memory or a DRAM memory) as shown in FIGS. 1-3. Memory controller 706 (a.k.a., a controller circuit) is coupled to memory device 704 and host device 708. Consistent with implementations of the present disclosure, memory device 704 can include a plurality of conductive interconnections through a cover layer that are in contact with conductive pads in a conductive pad layer, and memory controller 706 can be coupled to memory device 704 through at least one of the plurality of conductive interconnections. Memory controller 706 is configured to control memory device 704. For example, memory controller 706 may be configured to operate a plurality of channel structures via word lines. Memory controller 706 can manage data stored in memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program (or write) operations. Memory controller 706 can also be configured to manage various functions with respect to the data stored or to be stored in memory device 704 including, but not limited to bad-block management, garbage collection, logical-to-physical address conversion, wear leveling, etc. In some implementations, memory controller 706 is further configured to process error correction codes (ECCs) with respect to the data read from or written to memory device 704. Any other suitable functions may be performed by memory controller 706 as well, for example, formatting memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 7, memory controller 706 and a single memory device 704 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,. +−.10%,. +−.20%, or. +−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first semiconductor structure, a bonding structure, and a second semiconductor structure stacked along a first direction, wherein:
the first semiconductor structure is bonded to the second semiconductor structure through the bonding structure;
the bonding structure comprises a first group of contact structures, a second group of contact structures, and a dielectric material surrounding the first group of contact structures and the second group of contact structures;
a first contact structure of the first group of contact structures is adjacent to a second contact structure of the second group of contact structures along a second direction perpendicular to the first direction;
the first contact structure comprises a first conductive material; and
the second contact structure comprises the first conductive material and an oxide.

2. The semiconductor device of claim 1, wherein the first conductive material is a first metal, the oxide is a metal oxide, the metal oxide is a chemical compound of oxygen and elements from a second conductive material, and the second conductive material is a second metal.

3. The semiconductor device of claim 1, wherein the first contact structure comprises a first portion comprising the first conductive material, a second portion comprising the first conductive material, and a third portion comprising the first conductive material, the third portion is between the first portion and the second portion along the first direction, and the first conductive material in the third portion is re-solidified.

4. The semiconductor device of claim 1, wherein the bonding structure comprises a first dielectric layer in contact with the first semiconductor structure and a second dielectric layer in contact with the second semiconductor structure, the first group of contact structures and the second group of contact structures extend into the first dielectric layer and the second dielectric layer along the first direction, and a first dielectric material of the first dielectric layer is bonded to a second dielectric material of the second dielectric layer.

5. The semiconductor device of claim 1, wherein the first semiconductor structure comprises a first interconnect layer, the second semiconductor structure comprises a second interconnect layer, the first interconnect layer is coupled to the second interconnect layer through the first group of contact structures.

6. The semiconductor device of claim 1, wherein the first semiconductor structure comprises an array of memory cells, the second semiconductor structure comprises peripheral circuits configured to control the array of memory cells, and the array of memory cells are coupled to the peripheral circuits through the first group of contact structures.

7. The semiconductor device of claim 1, wherein the first semiconductor structure comprises a first array of dynamic random access memory (DRAM) cells, the second semiconductor structure comprises a second array of DRAM cells, and at least one of the first array or the second array is coupled to the first group of contact structures.

8. A semiconductor device, comprising:
a first semiconductor structure, a bonding structure, and a second semiconductor structure stacked along a first direction, wherein:
the first semiconductor structure is bonded to the second semiconductor structure through the bonding structure;
the bonding structure comprises contact structures and a dielectric material isolating the contact structures from one another; and
a first contact structure of the contact structures is conductive and comprises a first portion comprising a conductive material, a second portion comprising the conductive material, and a third portion being between the first portion and the second portion along the first direction and comprising the conductive material and an oxide.

9. The semiconductor device of claim 8, wherein the conductive material is a first metal, the oxide is a metal oxide, and the metal oxide is a chemical compound of oxygen and elements from a second metal.

10. The semiconductor device of claim 8, wherein the bonding structure comprises a first dielectric layer in contact with the first semiconductor structure and a second dielectric layer in contact with the second semiconductor structure, the contact structures extend into the first dielectric layer and the second dielectric layer along the first direction, and a first dielectric material of the first dielectric layer is bonded to a second dielectric material of the second dielectric layer.

11. The semiconductor device of claim 8, wherein the first semiconductor structure comprises a first interconnect layer, the second semiconductor structure comprises a second interconnect layer, and the first interconnect layer is coupled to the second interconnect layer through the contact structures.

12. The semiconductor device of claim 8, wherein the first semiconductor structure comprises an array of memory cells, the second semiconductor structure comprises peripheral circuits configured to control the array of memory cells, and the array of memory cells are coupled to the peripheral circuits through the contact structures.

13. The semiconductor device of claim 8, wherein the first semiconductor structure comprises a first array of dynamic random access memory (DRAM) cells, the second semiconductor structure comprises a second array of DRAM cells, and at least one of the first array or the second array is coupled to the contact structures.

14. The semiconductor device of claim 8, wherein the semiconductor device comprises two side regions and a center region between the two side regions along a second direction perpendicular to the first direction, and the contact structures are within the center region.

15. A method, comprising:
forming a first semiconductor structure;
forming a second semiconductor structure; and
forming a bonding structure between the first semiconductor structure and the second semiconductor structure along a first direction to bond the first semiconductor structure to the second semiconductor structure, wherein forming the bonding structure comprises:
forming a first group of contact structures and a second group of contact structures of the bonding structure, wherein:
a dielectric material of the bonding structure surrounds the first group of contact structures and the second group of contact structures;
a first contact structure of the first group of contact structures is adjacent to a second contact structure of the second group of contact structures along a second direction perpendicular to the first direction;
the first contact structure comprises a first conductive material; and
the second contact structure comprises the first conductive material and a first oxide.

16. The method of claim 15, wherein forming the first group of contact structures and the second group of contact structures of the bonding structure comprises:
forming a first bonding layer on a side of the first semiconductor structure, wherein the first bonding layer comprises the dielectric material, a first group of conductive pads, and a first group of thermite structures, and the first group of conductive pads are coupled to a first interconnect layer of the first semiconductor structure; and
forming a second bonding layer on a side of the second semiconductor structure, wherein the second bonding layer comprises the dielectric material, a second group of conductive pads, and a second group of thermite structures, the second group of conductive pads are coupled to a second interconnect layer of the second semiconductor structure, the first group of conductive pads are associated with the second group of conductive pads along the first direction, and the first group of thermite structures are associated with the second group of thermite structures along the first direction.

17. The method of claim 16, wherein a first conductive pad of the first group of conductive pads is adjacent to a first thermite structure of the first group of thermite structures, the first conductive pad comprises the first conductive material, the first conductive pad and the first thermite structure are isolated by the dielectric material, a second conductive pad of the second group of conductive pads is adjacent to a second thermite structure of the second group of thermite structures, the second conductive pad comprises the first conductive material, and the second conductive pad and the second thermite structure are isolated by the dielectric material.

18. The method of claim 17, wherein the first thermite structure comprises a second conductive material, the second thermite structure comprises a second oxide, the first conductive material comprises a first metal, the second conducive material comprises a second metal, the second oxide comprises a chemical compound of oxygen and elements from the first metal.

19. The method of claim 18, wherein the first thermite structure and the second thermite structure both comprise multiple layers of the second metal and the second oxide alternating with each other along the first direction.

20. The method of claim 17, further comprising:
aligning the first semiconductor structure with the second semiconductor structure, wherein the first conductive pad is aligned with the second conductive pad along the first direction, and the first thermite structure is aligned with the second thermite structure along the first direction;
stacking the first semiconductor structure on the second semiconductor structure to make the first group of conductive pads in contact with the second group of conductive pads and make the first group of thermite structures in contact with the second group of thermite structures; and
triggering a chemical reaction between the first group of thermite structures and the second group of thermite structures, wherein heat produced by the chemical reaction melts a side of the first conductive pad and a side of the second conductive pad and bonds the first conductive pad to the second conductive pad, the first contact structure is formed from the first conductive pad and the second conductive pad, and the second contact structure is formed by the chemical reaction between the first thermite structure and the second thermite structure.
